(19) United States
(12) Patent Application Publication
(10) Pub. No.: US 2023/0278173 A1
(43) Pub. Date: Sep. 7, 2023

(54) VACUUM PRESSURE SUPPLY SYSTEM

(71) Applicant: FANUC CORPORATION, Minamitsuru-gun, Yamanashi-ken (JP)

(72) Inventors: Makito NAKAMURA, Minamitsuru-gun, Yamanashi-ken (JP); Masahiro MUROTA, Minamitsuru-gun, Yamanashi-ken (JP)

(73) Assignee: FANUC CORPORATION, Minamitsuru-gun, Yamanashi-ken (JP)

(21) Appl. No.: 18/005,539

(22) PCT Filed: Jul. 12, 2021
(86) PCT No.: PCT/JP2021/026061

§ 371 Date: Jan. 13, 2023

(30) Foreign Application Priority Data
Jul. 17, 2020 (JP) 2020-122819

(51) Int. Cl. B25B 11/00; G05D 15/01

(52) U.S. Cl. CPC B25B 11/005; G05D 15/01

(57) ABSTRACT

A vacuum pressure supply system comprises: a plurality of vacuum pressure supply paths for supplying a vacuum pressure from a vacuum source to a holding unit that holds an object using the vacuum pressure; a pressure adjusting mechanism that adjusts the pressure in the vacuum pressure supply paths to obtain mutually different holding forces for holding the object; and a switching mechanism that switches the connection state of the vacuum source and the plurality of vacuum pressure supply paths in order to change the holding force of the holding unit. The switching mechanism switches the connection state by selecting one of the vacuum pressure supply paths and connecting the selected vacuum pressure supply path to the vacuum source.

### TECHNICAL FIELD

The present invention relates to a vacuum pressure supply system.

### BACKGROUND ART

In various fields, an object holding device (for example, a vacuum chuck device) that holds an object by using vacuum pressure is used. For example, in a machine tool, a workpiece is held using such a vacuum chuck device. Here, it is preferably possible to select from a plurality of magnitude settings of a holding force for holding an object, in response to the weight, strength, or the like of the object to be held. For example, JP 2006-229027 A discloses a wafer transfer device having a flow rate regulating valve for regulating a vacuum pressure for holding a wafer.

### SUMMARY OF THE INVENTION

However, it takes time to adjust the vacuum pressure by such a flow rate regulating valve. In order to shorten the time for such adjustment, for example, it is conceivable to switch the holding forces by using a plurality of vacuum sources (for example, vacuum pumps) corresponding to a plurality of setting values for holding force magnitude. However, the use of a plurality of vacuum sources causes an increase in the size of the device.

An object of the present invention is to provide a vacuum pressure supply system capable of switching holding forces without using a plurality of vacuum sources.

According to an aspect of the present invention, there is provided a vacuum pressure supply system including: a plurality of vacuum pressure supply paths each configured to supply a vacuum pressure from a vacuum source to a holding unit configured to hold an object using the vacuum pressure; a pressure adjustment mechanism configured to adjust pressures in the plurality of vacuum pressure supply paths in a manner so that holding forces for holding the object are different from each other; and a switching mechanism configured to switch connection states between the vacuum source and the plurality of vacuum pressure supply paths in order to change a holding force of the holding unit. The switching mechanism switches the connection states by selecting one of the vacuum pressure supply paths and connecting the selected vacuum pressure supply path to the vacuum source.

According to the present invention, it is possible to provide a vacuum pressure supply system capable of switching the holding forces without using a plurality of vacuum sources.

### BRIEF DESCRIPTION OF DRAWINGS

FIG. 1 is a diagram illustrating a configuration of a vacuum pressure supply system according to an embodiment;

FIG. 2 is a diagram illustrating an example of an operation procedure of the vacuum pressure supply system according to the embodiment;

FIG. 3 is a diagram illustrating a configuration of a vacuum pressure supply system according to a first modification; and

FIG. 4 is a diagram illustrating an example of an operation procedure of the vacuum pressure supply system according to the first modification.

### DETAILED DESCRIPTION OF THE INVENTION

Hereinafter, a vacuum pressure supply system according to an embodiment of the present invention will be described in detail.

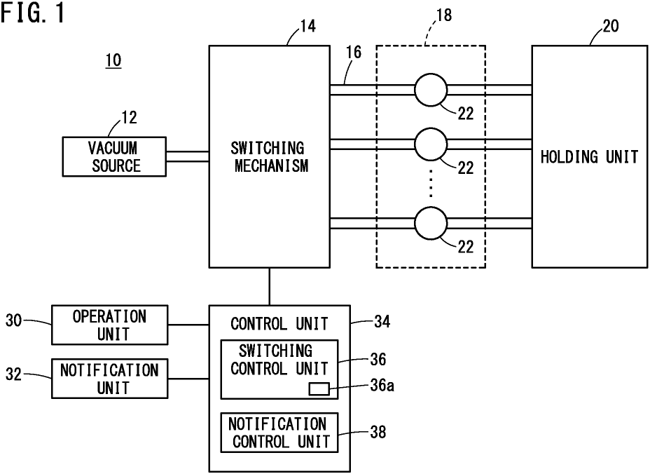

FIG. 1 is a diagram illustrating a configuration of a vacuum pressure supply system 10 according to an embodiment. The vacuum pressure supply system 10 includes a vacuum source 12, a switching mechanism 14, a plurality of vacuum pressure supply paths 16, a pressure adjustment mechanism 18, a holding unit 20, an operation unit 30, a notification unit 32, and a control unit 34. One example of the vacuum pressure supply system 10 is a vacuum chuck device.

The vacuum source 12 is, for example, a vacuum pump, and generates a vacuum pressure to be supplied to the holding unit 20. In the description, the vacuum pressure means a pressure state (reduced-pressure state) in which the pressure is lower than the atmospheric pressure, and does not necessarily have to be a complete vacuum.

The plurality of vacuum pressure supply paths 16 are connected to the holding unit 20. The plurality of vacuum pressure supply paths 16 are connected to the vacuum source 12 via the switching mechanism 14. In the present embodiment, for the sake of convenience, the number of vacuum pressure supply paths 16 is five. The switching mechanism 14 switches the connection states between the vacuum source 12 and the five vacuum pressure supply paths 16 in order to change a holding force of the holding unit 20. For example, the switching mechanism 14 can switch the connection states between the vacuum source 12 and the five vacuum pressure supply paths 16 by selecting one of the five vacuum pressure supply paths 16 and connecting the selected one to the vacuum source 12. With this configuration, the vacuum pressure generated by the vacuum source 12 is supplied to one of the vacuum pressure supply paths 16, and it is possible to switch the vacuum pressure supply paths 16 to which the vacuum pressure is supplied. Hereinafter, connection states between the vacuum source 12 and the five vacuum pressure supply paths 16 may be simply referred to as “connection states”.

As will be described later, the pressures of the five vacuum pressure supply paths 16 are different from each other. Therefore, by selecting one of the five vacuum pressure supply paths 16 and connecting it to the vacuum source 12, it is possible to change the holding force with which the holding unit 20 holds an object. That is, the holding force (pressure) of the holding unit 20 can be changed to the holding force (pressure) corresponding to the selected vacuum pressure supply path 16. The switching mechanism 14 can also switch the connection states by connecting none of the five vacuum pressure supply paths 16 to the vacuum source 12. In this case, since the holding unit 20 is not substantially connected to the vacuum source 12, the holding force with which the holding unit 20 holds the object becomes 0 (i.e., the difference between the pressure of the holding unit 20 and the atmospheric pressure is 0 kPa). As described above, the holding force of the holding unit 20 can be changed by the switching mechanism 14 switching the connection states. The connection states switched by the switching mechanism 14 include a total of six states: five states in each of which the vacuum source 12 is connected to one of the five vacuum pressure supply paths 16 and one state in which none of the vacuum pressure supply paths 16 is connected to the vacuum source 12.

The pressure adjustment mechanism 18 adjusts the pressures in the vacuum pressure supply paths 16 such that the force with which the holding unit 20 holds the object varies. The pressure adjustment mechanism 18 adjusts the pressures in the five vacuum pressure supply paths 16 to be different from each other. For example, the pressure adjustment mechanism 18 adjusts the pressures (differential pressures with respect to the atmospheric pressure) in the five vacuum pressure supply paths 16 to -75 kPa(G), -60 kPa(G), -45 kPa(G), -30 kPa(G), and -15 kPa(G). The differential pressures correspond to the respective holding forces of the holding unit 20. That is, as the differential pressure decreases (as the absolute value of the differential pressure increases), the holding force of the holding unit 20 increases. Since there is a correlation between the holding force and the differential pressure, hereinafter the holding force may be expressed by the differential pressure.

Here, the pressure adjustment mechanism 18 includes five throttle valves 22 provided in the respective five vacuum pressure supply paths 16. By adjusting the flow rate of each of the vacuum pressure supply paths 16 using the five throttle valves 22, the pressures in the five vacuum pressure supply paths 16 can be made different from each other. Note that the throttle valves 22 may not be provided in the vacuum pressure supply paths 16. For example, the flow rates in the vacuum pressure supply paths 16 (the pressures in the vacuum pressure supply paths 16) may be made different from each other by making the inner diameters of the vacuum pressure supply paths 16 different from each other.

The holding unit 20 suctions and holds an object by using the vacuum pressure supplied from the vacuum source 12 via the vacuum pressure supply path 16. An example of the holding unit 20 is a vacuum chuck mechanism. As described above, the switching mechanism 14 can change the holding force of the holding unit 20 by switching the connection states between the vacuum source 12 and the five vacuum pressure supply paths 16. As a result, it is possible to switch the holding forces using a single vacuum source 12. That is, since it is unnecessary to provide a plurality of vacuum sources 12 depending on a plurality of setting values for the holding forces, the installation space can be reduced in size and the device also can be reduced in size.

Here, it takes a certain amount of time (for example, 0.1 to 1 seconds) from the switching of the connection states between the vacuum source 12 and the vacuum pressure supply paths 16 until the completion of the change of the holding force of holding unit 20. That is, even when the connection states have been switched, the suction pressure (the pressure used for suctioning the object) of the holding unit 20 is not immediately changed. By switching the connection states, the holding force (suction pressure) of the holding unit 20 starts to change (start of change of the holding force). Thereafter, the holding force of the holding unit 20 reaches the holding force (suction pressure) corresponding to the vacuum pressure supply path 16 after the switching (completion of the change).

The operation unit 30 is an input device for an operator to perform an operation for changing the holding force of the holding unit 20, and the operation unit is, for example, a switch, a keyboard, or a touch panel. The operator selects the holding force of the holding unit 20 using the operation unit 30. The number and magnitude of the holding forces which the operator can select depends on the five vacuum pressure supply paths 16. In the present embodiment, the number of selectable holding forces is six. Therefore, in the present embodiment, the operator selects one of [holding force: -75 kPa(G)], [holding force: -60 kPa(G)], [holding force: -45 kPa(G)], [holding force: -30 kPa(G)], [holding force: -15 kPa(G)], and [holding force: 0 kPa(G)].

The notification unit 32 is a sound output device (for example, a speaker), an image display device (for example, a liquid crystal display device or an EL display device), or a light output device (for example, an LED device), and is controlled by a notification control unit 38. The notification unit 32 notifies that the holding force of the holding unit 20 is to be changed from now (advance notice of changing of the holding force) or that the holding force of the holding unit 20 has changed as a result of switching of the connection states (a change in the holding force), or the like, by using sound, an image, or light.

The control unit 34 is configured by, for example, hardware (processor) and software (program), and is divided into a switching control unit 36 and the notification control unit 38.

The switching control unit 36 controls the switching mechanism 14 to change the holding force of the holding unit 20. The switching control unit 36 controls the switching mechanism 14 in accordance with an operation performed on the operation unit 30 by the operator. When the operator operates the operation unit 30, the switching control unit 36 controls the switching mechanism 14 after a first predetermined time has elapsed since the operation performed by the operator, and then switches the connection states between the vacuum source 12 and the five vacuum pressure supply paths 16. The switching control unit 36 has a table 36a in which the plurality of holding forces which the operator can select and the connection states between the vacuum source 12 and the five vacuum pressure supply paths 16 are stored in association with each other. That is, the table 36a associates the plurality of holding forces which the operator can select, with the vacuum pressure supply paths 16 to be selected to realize the respective multiple holding forces. The switching control unit 36 controls the switching mechanism 14 with reference to the table 36a.

Before the connection states between the vacuum source 12 and the five vacuum pressure supply paths 16 are switched, the notification control unit 38 causes the notification unit 32 to notify that the holding force of the holding unit 20 is to be changed from now (advance notice of changing of the holding force). When the holding force of the holding unit 20 becomes weak, there are cases where it may be difficult for the holding unit 20 to appropriately hold an object. As such, before the connection states between the vacuum source 12 and the five vacuum pressure supply paths 16 are switched, it is possible to alert the operator by notifying that the holding force is to be changed from now.

The notification control unit 38 causes the notification unit 32 to notify that the holding force of the holding unit 20 has changed due to the switching of the connection states (notice of the changed holding force). By receiving the notice of the changed holding force, the operator can recognize that the holding force has changed. That the holding force of the holding unit 20 has changed means that the holding force is currently being changed or the changing of the holding force has been completed.

The notification control unit 38 can give an advance notice of changing of the holding force of the holding unit 20 and a notice of the changed holding force, as follows. In this case, the notification unit 32 is, for example, a speaker. That is, before the first predetermined time elapses from the operation performed by the operator (before the switching control unit 36 switches the connection states), the notification control unit 38 causes the notification unit 32 to output an advance notice sound for notifying in advance that the holding force of the holding unit 20 is to be changed from now. After the elapse of the first predetermined time, the notification control unit 38 causes the notification unit 32 to output a notification sound notifying that the holding force of the holding unit 20 has changed. Thus, the operator can grasp the progress of the changing of the holding force by the advance notice sound and the notification sound.

The notification control unit 38 may divide the notification sound into a first notification sound and a second notification sound, and cause the notification unit 32 to output the first notification sound and the second notification sound. That is, when the first predetermined time elapses from the operation performed by the operator, the notification control unit 38 causes the first notification sound notifying that the holding force is currently being changed, to be outputted. Thereafter, the notification control unit 38 causes the second notification sound notifying that the changing to the holding force selected (designated) by the operator has been completed, to be outputted. As a result, the operator can grasp the change situation of the holding force in more detail by the first notification sound and the second notification sound.

In this case, the notification control unit 38 causes the notification unit 32 to output the advance notice sound and the notification sound in different modes. The notification control unit 38 causes the first notification sound and the second notification sound to be output in different modes. The mode of the sound means any one of the magnitude (volume) of the sound, the pitch (musical pitch) of the sound, the pattern of the sound, and the output interval of the sound, or a combination thereof. For example, an intermittent sound (for example, “beep beep, beep beep, beep beep, ...”) may be used as the advance notice sound, and a continuous sound (for example, “beep”) may be used as the notification sound. Further, the notification sound can be divided into the first notification sound (indicating that the holding force is currently being changed) and the second notification sound (indicating the completion of the changing) by changing the volume or the pitch of the notification sound “beep” halfway through the outputting thereof.

The notification control unit 38 may perform at least one of a volume processing for increasing the volume of the advance notice sound with the lapse of time, a pitch processing for raising the pitch of the advance notice sound with the lapse of time, or an output interval processing for shortening the output interval of the advance notice sound with the lapse of time. Accordingly, the operator can recognize that the timing of switching of the connection states (start of changing of the holding force) is approaching.

The notification control unit 38 can determine that the changing of the holding force has been completed in the following manner. That is, when the first predetermined time elapses from the operation performed by the operator and then the second predetermined time further elapses, the notification control unit 38 determines that the changing of the holding force has been completed. The second predetermined time corresponds to a time required from the switching of the connection states to the completion of the changing of the holding force. In general, if the size and the like of the vacuum pressure supply system 10 are determined, the required time is also generally determined. In other words, the second predetermined time can be a constant value. However, the time required to complete the changing of the holding force also changes in accordance with the difference between the holding force (the pressure of the vacuum pressure supply path 16) before the change and the (selected) holding force (the pressure of the vacuum pressure supply path 16) after the change. Therefore, the notification control unit 38 may change the length of the second predetermined time in accordance with the selected holding force (vacuum pressure supply path 16) using a table (not shown). This table represents, for example, a correspondence relationship between the holding force (vacuum pressure supply path 16) before change, the holding force (vacuum pressure supply path 16) after change, and the second predetermined time. Note that this table may be included in the table 36a.

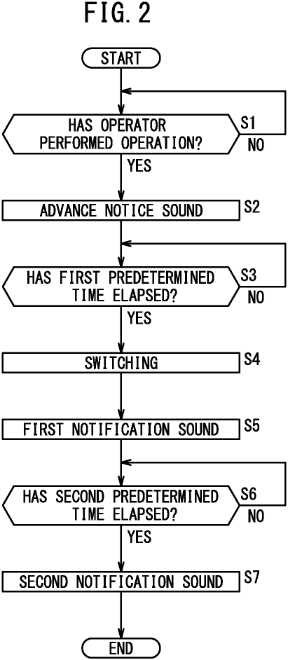

FIG. 2 is a diagram illustrating an example of an operation procedure of the vacuum pressure supply system 10 according to the embodiment. When the operator performs an operation for changing the holding force of the holding unit 20 on the operation unit 30 (YES in step S1), the notification control unit 38 causes the notification unit 32 (a speaker in this case) to output the advance notice sound for notifying in advance that the holding force of the holding unit 20 is due to be changed (step S2).

After the first predetermined time has elapsed from the operation performed by the operator (YES in step S3), the switching control unit 36 controls the switching mechanism 14 to switch the connection states between the vacuum source 12 and the five vacuum pressure supply paths 16 (step S4). On the other hand, when the first predetermined time has not elapsed from the operation performed by the operator (NO in step S3), the notification control unit 38 waits in step S3 until the first predetermined time elapses. The lapse of time can be measured by, for example, starting time measurement with a timer at the time of the operation having been performed by the operator. When the notification control unit 38 determines NO in step S3, the notification control unit 38 may return to step S2. Thus, the advance notice sound is continuously outputted until the first predetermined time elapses.

After the first predetermined time has elapsed since the operation performed by the operator, the notification control unit 38 causes the notification unit 32 to output the first notification sound for notifying that the holding force of the holding unit 20 is currently being changed (step S5). The first notification sound is preferably output from the notification unit 32 at the time of switching of the vacuum pressure supply paths 16 or immediately after the switching. Further, after the first predetermined time has elapsed and then the second predetermined time has further elapsed (YES in step S6), the notification control unit 38 causes the notification unit 32 to output the second notification sound for notifying that the changing of the holding force of the holding unit 20 has been completed (step S7). On the other hand, when the second predetermined time has not elapsed since the switching of the connection states between the vacuum source 12 and the five vacuum pressure supply paths 16 (NO in step S6), the notification control unit 38 waits in step S6 until the second predetermined time elapses. Owing to this configuration, the operator can grasp the change situation of the holding force by the first notification sound and the second notification sound. When the notification control unit 38 determines NO in step S6, the notification control unit 38 may return to step S5. Thus, the first notification sound is continuously outputted until the second predetermined time elapses.

As described above, in the present embodiment, by switching the connection states between the vacuum source 12 and the plurality of vacuum pressure supply paths 16, the switching mechanism 14 can change the holding force of the holding unit 20 without using a plurality of vacuum sources. The notification control unit 38 causes the advance notice sound to be output before the switching. In addition, the notification control unit 38 causes the first notification sound and the second notification sound to be output while the holding force is changing by the switching and after the completion of the changing. As a result, the operator can grasp the change state of the holding force.

### Modification 1

In the embodiment, the notification control unit 38 determines the completion of the change of the holding force based on the elapse of the second predetermined time. However, the notification control unit 38 may determine the completion of the change of the holding force by another method.

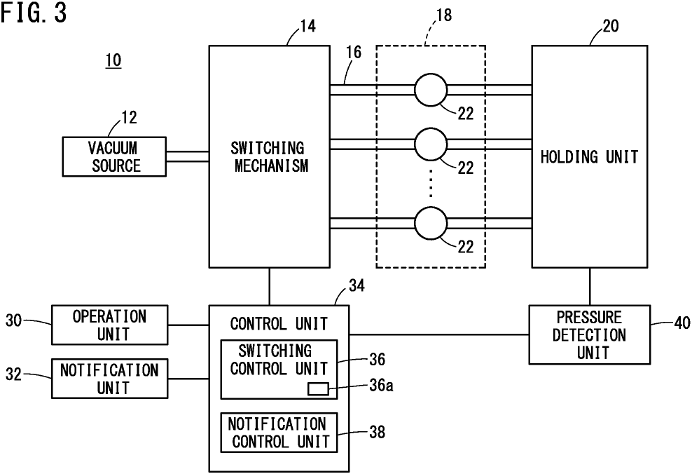

FIG. 3 is a diagram illustrating a configuration of a vacuum pressure supply system 10 according to a first modification. The same components as those of the above-described embodiment are denoted by the same reference numerals, and only different portions will be described. The vacuum pressure supply system 10 includes a pressure detection unit 40. The pressure detection unit 40 is provided in the holding unit 20 and detects the suction pressure of the holding unit 20. The notification control unit 38 determines whether or not the change of the holding force has been completed based on a detection signal from the pressure detection unit 40. As described above, the suction pressure of the holding unit 20 indicated by the detection signal corresponds to the holding force and changes together with the holding force. The completion of the change of the holding force can be determined based on whether or not the detected suction pressure (holding force) has reached the selected suction pressure (holding force). When the notification control unit 38 determines that the changing of the holding force has been completed, the notification control unit 38 causes the notification unit 32 to output the second notification sound notifying that the changing of the holding force has been completed.

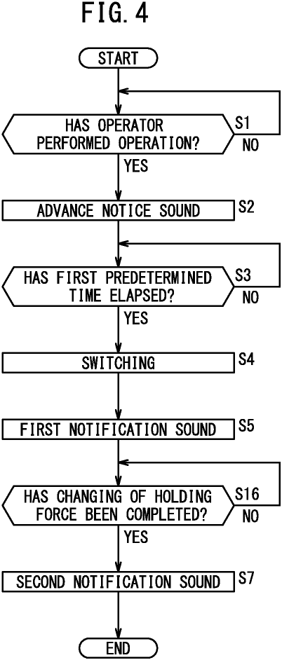

FIG. 4 is a diagram illustrating an example of an operation procedure of the vacuum pressure supply system 10 according to the first modification. In this modification, since steps S1 to S5 are the same as steps S1 to S5 of the embodiment, steps subsequent to step S5 will be described. After the notification control unit 38 causes the notification unit 32 to output the first notification sound (step S5), the notification control unit 38 determines whether or not the changing of the holding force has been completed (step S16). When the notification control unit 38 determines that the changing of the holding force has been completed (YES in step S16), the notification control unit 38 causes the notification unit 32 to output the second notification sound (step S7). On the other hand, when the notification control unit 38 determines that the changing of the holding force is not completed (NO in step S16), the notification control unit 38 waits in step S16 until the notification control unit 38 determines that the changing of the holding force has been completed. Owing to this configuration, the operator can grasp the change situation of the holding force by the first notification sound and the second notification sound. When the notification control unit 38 determines NO in step S16, the notification control unit 38 may return to step S5. In this case, the first notification sound is continuously notified until the changing of the holding force is completed.

Except for the above points, the first modification is the same as the embodiment, and thus detailed descriptions thereof will be omitted.

### Modification 2

In the embodiment, before the connection states are switched, the notification control unit 38 causes the notification unit 32 to notify that the holding force is due to be changed. Here, the notifying may be performed only when the holding force of the holding unit 20 is due to decrease by switching of the connection states, and the notifying may not be performed when the holding force is due to increase. Accordingly, it is possible to alert the operator only when the holding force is due to decrease (as an example, only when the holding force is due to become 0).

Here, when the holding force is due to increase by switching of the connection states, the notification control unit 38 may output none of the advance notice sound, the first notification sound, and the second notification sound. However, even in a case where the holding force is due to increase by switching of the connection states, the notification control unit 38 may output at least one of the advance notice sound, the first notification sound, or the second notification sound (for example, only the second notification sound indicating completion of changing of the holding force).

In addition, when the holding force is due to increase by switching of the connection states, the switching control unit 36 may control the switching mechanism 14 to change the holding force of the holding unit 20 immediately after the operation performed by the operator, without waiting for the elapse of the first predetermined time from the operation performed by the operator. This allows the vacuum pressure supply system 10 to operate quickly. In this case, the advance notice sound is not notified.

Except for the above points, the second modification is the same as the embodiment, and thus detailed descriptions thereof will be omitted.

### Modification 3

In the embodiment, the switching control unit 36 switches the holding forces based on the operation of the operator. However, the switching control unit 36 may control the switching mechanism 14 and thereby change the holding force based on a program, not based on the operation of the operator. In this case, step S1 is omitted from the operation procedures shown in FIGS. 2 and 4. That is, the notification control unit 38 causes the advance notice sound to be output (step S2) before the switching (step S4). The switching control unit 36 switches the connection states between the vacuum source 12 and the plurality of vacuum pressure supply paths 16 (step S4) after the first predetermined time has elapsed from the start of outputting the advance notice sound (YES in step S3).

After the elapse of the first predetermined time from the start of outputting the advance notice sound (i.e., at the time of switching the vacuum pressure supply paths 16 or immediately thereafter), the notification control unit 38 causes the notification unit 32 to output the first notification sound (step S5). Thereafter, in the case of the embodiment (FIG. 2), after the first predetermined time has elapsed and further after the second predetermined time has elapsed (YES in step S6), the notification control unit 38 causes the second notification sound to be output (step S7). In the case of the first modification (FIG. 4), when the notification control unit 38 determines that the change of the holding force has been completed (YES in step S16) regardless of the elapse of time, the notification control unit 38 causes the second notification sound to be output (step S7). In this way, the notification control unit 38 begins to switch the connection states at the time of start of outputting of the advance notice sound, and then the notification control unit 38 causes the first notification sound (and the second notification sound) to be output.

Except for the points described above, the third modification is the same as the embodiment, and detailed descriptions thereof will be omitted.

### Modification 4

In the embodiment, the switching control unit 36 sets the holding force of the holding unit 20 to 0 by connecting none of the plurality of vacuum pressure supply paths 16 to the vacuum source 12. However, the switching control unit 36 may set the holding force to 0 by connecting the selected vacuum pressure supply path 16 to the vacuum source 12. That is, the throttle valve 22 of a specific vacuum pressure supply path 16 is closed, and the switching control unit 36 connects this vacuum pressure supply path 16 to the vacuum source 12. In this way, the holding force can be made 0 without disconnecting all of the plurality of vacuum pressure supply paths 16.

Except for the above points, the modification 4 is the same as the embodiment, and thus detailed description thereof will be omitted.

The above-described embodiment and Modifications 1 to 4 can be appropriately combined. That is, all or a part of the configurations of the first to fourth modifications can be applied to the embodiment.

### Invention Obtained From the Embodiment

Inventions that can be grasped from the above-described embodiment and Modifications 1 to 4 will be described below.

[1] According to the present invention, the vacuum pressure supply system (10) includes: the plurality of vacuum pressure supply paths (16) each configured to supply the vacuum pressure from the vacuum source (12) to the holding unit (20) configured to hold an object using the vacuum pressure; the pressure adjustment mechanism (18) configured to adjust the pressures in the plurality of vacuum pressure supply paths in a manner so that the holding forces for holding the object are different from each other; and the switching mechanism (14) configured to switch the connection states between the vacuum source and the plurality of vacuum pressure supply paths in order to change the holding force of the holding unit. The switching mechanism switches the connection states by selecting one of the vacuum pressure supply paths and connecting the selected vacuum pressure supply path to the vacuum source. With this configuration, the holding force of the holding unit can be changed by switching the connection states between the vacuum source and the plurality of vacuum pressure supply paths. In other words, the holding force can be changed without using a plurality of vacuum sources.

[2] The switching mechanism switches the connection states such that none of the plurality of vacuum pressure supply paths is connected to the vacuum source. Accordingly, the holding force of the holding unit can be set to 0 by connecting none of the plurality of vacuum pressure supply paths to the vacuum source.

[3] The vacuum pressure supply system further includes: the switching control unit (36) configured to control the switching mechanism to switch the connection states in order to change the holding force of the holding unit; and the notification control unit (38) configured to, before the connection states are switched, cause the notification unit (32) to notify that the holding force is due to be changed. Accordingly, it is possible to alert the operator by notifying in advance that the holding force is due to be changed.

[4] The notification control unit causes the notification unit to notify that the holding force has changed due to switching of the connection states. Accordingly, the operator can recognize that the holding force has changed by receiving the notification that the holding force has changed.

[5] The notification control unit causes the notification unit to notify that the holding force is to be changed only when the holding force is to decrease due to the switching of the connection states. This makes it possible to alert the operator only when the holding force is due to decrease.

[6] The vacuum pressure supply system further includes the operation unit (30) on which an operator performs an operation for changing the holding force, and the switching control unit controls the switching mechanism in accordance with the operation performed by the operator. Accordingly, it is possible to change the holding force of the holding unit by the operation of the operator.

[7] The notification unit is a speaker. The switching control unit switches the connection states after the first predetermined time has elapsed from the operation performed by the operator. The notification control unit causes the notification unit to output an advance notice sound notifying in advance that the holding force is due to be changed, before the first predetermined time elapses from the operation performed by the operator, and causes the notification unit to output a notification sound notifying that the holding force has changed, after the first predetermined time has elapsed. As a result, the operator can grasp the change situation of the holding force of the holding unit by the advance notice sound and the notification sound.

[8] The notification control unit causes the advance notice sound and the notification sound to be output in different modes. This makes it easy for the operator to distinguish between the advance notice sound and the notification sound, and makes it possible to more reliably grasp the progress of the holding force change.

[9] When the first predetermined time has elapsed from the operation performed by the operator, the notification control unit causes the first notification sound indicating that the holding force is currently being changed to be output, and thereafter causes the second notification sound indicating that the changing of the holding force has been completed to be output. As a result, the operator can grasp the change situation of the holding force in more detail by the first notification sound and the second notification sound.

[10] The notification control unit causes the first notification sound and the second notification sound to be output in different modes. Owing to this configuration, the operator can easily distinguish between the first notification sound and the second notification sound, and during the change of the holding force, the transition to the completion of the change can be more reliably grasped.

[11] The notification control unit determines that the changing of the holding force has been completed when the first predetermined time elapses from the operation performed by the operator and thereafter the second predetermined time further elapses. Accordingly, it is possible to determine that the changing of the holding force has been completed without detecting the suction pressure of the holding unit.

[12] The vacuum pressure supply system further includes the pressure detection unit (40) configured to detect the suction pressure of the holding unit, and the notification control unit determines whether or not the changing of the holding force has been completed, based on a detection signal of the pressure detection unit. Accordingly, by detecting the suction pressure of the holding unit, it is possible to more reliably determine whether or not the changing of the holding force has been completed.

[13] The pressure adjustment mechanism includes the plurality of throttle valves (22) provided in the plurality of vacuum pressure supply paths. This makes it possible to adjust the pressures in the plurality of vacuum pressure supply paths such that the holding force for holding the object varies in the different vacuum pressure supply paths, by using the plurality of throttle valves.

1. A vacuum pressure supply system comprising:
a plurality of vacuum pressure supply paths each configured to supply a vacuum pressure from a vacuum source to a holding unit configured to hold an object using the vacuum pressure;
a pressure adjustment mechanism configured to adjust pressures in the plurality of vacuum pressure supply paths in a manner so that holding forces for holding the object are different from each other; and
a switching mechanism configured to switch connection states between the vacuum source and the plurality of vacuum pressure supply paths in order to change a holding force of the holding unit, wherein
the switching mechanism switches the connection states by selecting one of the vacuum pressure supply paths and connecting the selected vacuum pressure supply path to the vacuum source.

2. The vacuum pressure supply system according to claim 1, wherein
the switching mechanism switches the connection states in a manner so that none of the plurality of vacuum pressure supply paths is connected to the vacuum source.

3. The vacuum pressure supply system according to claim 1, further comprising:
a switching control unit configured to control the switching mechanism to switch the connection states in order to change the holding force of the holding unit; and
a notification control unit configured to cause a notification unit to notify that the holding force is due to be changed, before the connection states are switched.

4. The vacuum pressure supply system according to claim 3, wherein
the notification control unit causes the notification unit to notify that the holding force has changed due to switching of the connection states.

5. The vacuum pressure supply system according to claim 3, wherein
the notification control unit causes the notification unit to notify that the holding force is due to be changed, only when the holding force is to decrease due to switching of the connection states.

6. The vacuum pressure supply system according to claim 3, further comprising:
an operation unit on which an operator performs an operation for changing the holding force,
wherein the switching control unit controls the switching mechanism in accordance with the operation performed by the operator.

7. The vacuum pressure supply system according to claim 6, wherein
the notification unit is a speaker,
the switching control unit switches the connection states after a first predetermined time has elapsed from the operation performed by the operator, and
the notification control unit causes the notification unit to output an advance notice sound notifying in advance that the holding force is due to be changed, before the first predetermined time elapses from the operation performed by the operator, and causes the notification unit to output a notification sound notifying that the holding force has changed, after the first predetermined time has elapsed.

8. The vacuum pressure supply system according to claim 7, wherein
the notification control unit causes the advance notice sound and the notification sound to be output in different modes.

9. The vacuum pressure supply system according to claim 7, wherein
when the first predetermined time has elapsed from the operation performed by the operator, the notification control unit causes a first notification sound indicating that the holding force is currently being changed to be output, and thereafter causes a second notification sound indicating that changing of the holding force has been completed to be output.

10. The vacuum pressure supply system according to claim 9, wherein
the notification control unit causes the first notification sound and the second notification sound to be output in different modes.

11. The vacuum pressure supply system according to claim 9, wherein
the notification control unit determines that the changing of the holding force has been completed when the first predetermined time elapses from the operation performed by the operator and thereafter a second predetermined time further elapses.

12. The vacuum pressure supply system according to claim 9, further comprising:
a pressure detection unit configured to detect a suction pressure of the holding unit,
wherein the notification control unit determines whether or not the changing of the holding force has been completed, based on a detection signal of the pressure detection unit.

13. The vacuum pressure supply system according to claim 1, wherein
the pressure adjustment mechanism includes a plurality of throttle valves provided in the plurality of vacuum pressure supply paths.
